(19) United States
(12) Patent Application Publication
(10) Pub. No.: US 2025/0048547 A1
(43) Pub. Date: Feb. 6, 2025

(54) DAMPENING GOLD FINGER RESONANCE

(71) Applicant: DELL PRODUCTS L.P., Round Rock, TX (US)

(72) Inventors: Arun Chada, Pflugerville, TX (US); Doug Wallace, Round Rock, TX (US); Bhyrav Mutnury, Austin, TX (US)

(21) Appl. No.: 18/364,705

(22) Filed: Aug. 3, 2023

(51) Int. Cl. H05K 1/02; H05K 1/11

(52) U.S. Cl. CPC H05K 1/0298; H05K 1/0222; H05K 1/114; H05K 2201/09354

(57) ABSTRACT

An add-in card includes a card-edge connector including a signal contact finger and a ground contact finger coupled to a ground plane of the add-in card, a plurality of metal layers, and first and second ground vias. The metal layers include a surface metal layer, a first ground metal layer, and a second ground metal layer. The surface metal layer includes the signal contact finger and the ground contact finger. The first ground metal layer is a closest metal layer to the surface metal layer, and the second ground metal layer is farther from the surface metal layer than the first ground metal layer. The first ground via is coupled to a first end of the ground contact finger, the first ground metal layer, and the second ground metal layer. The second ground via is coupled to a second end of the ground contact finger and the second ground metal layer, but is not coupled to the first ground metal layer.

### FIELD OF THE DISCLOSURE

This disclosure generally relates to information handling systems, and more particularly relates to dampening gold finger resonance in an information handling system.

### BACKGROUND

As the value and use of information continues to increase, individuals and businesses seek additional ways to process and store information. One option is an information handling system. An information handling system generally processes, compiles, stores, and/or communicates information or data for business, personal, or other purposes. Because technology and information handling needs and requirements may vary between different applications, information handling systems may also vary regarding what information is handled, how the information is handled, how much information is processed, stored, or communicated, and how quickly and efficiently the information may be processed, stored, or communicated. The variations in information handling systems allow for information handling systems to be general or configured for a specific user or specific use such as financial transaction processing, reservations, enterprise data storage, or global communications. In addition, information handling systems may include a variety of hardware and software resources that may be configured to process, store, and communicate information and may include one or more computer systems, data storage systems, and networking systems.

### SUMMARY

An add-in card may include a card-edge connector including a signal contact finger and a ground contact finger coupled to a ground plane of the add-in card, a plurality of metal layers, and first and second ground vias. The metal layers may include a surface metal layer, a first ground metal layer, and a second ground metal layer. The surface metal layer may include the signal contact finger and the ground contact finger. The first ground metal layer may be a closest metal layer to the surface metal layer, and the second ground metal layer may be farther from the surface metal layer than the first ground metal layer. The first ground via may be coupled to a first end of the ground contact finger, the first ground metal layer, and the second ground metal layer. The second ground via may be coupled to a second end of the ground contact finger and the second ground metal layer, but not to the first ground metal layer.

### BRIEF DESCRIPTION OF THE DRAWINGS

It will be appreciated that for simplicity and clarity of illustration, elements illustrated in the Figures have not necessarily been drawn to scale. For example, the dimensions of some of the elements are exaggerated relative to other elements. Embodiments incorporating teachings of the present disclosure are shown and described with respect to the drawings presented herein, in which:

FIGS. 1A-1D illustrate various elements of an arrangement for connecting an add-in card to a motherboard;

FIG. 2 is a side view of a via-out-of-pad arrangement as may be known in the art;

FIG. 3 is a side view of a via-out-of-pad arrangement according to an embodiment of the present disclosure;

FIG. 4A is a graph of resonance versus frequency for a via-out-of-pad arrangement as may be known in the art;

FIG. 4B is a graph of resonance versus frequency for a via-out-of-pad arrangement according to an embodiment of the present disclosure; and

FIG. 5 is a block diagram of a general information handling system according to an embodiment of the present disclosure.

The use of the same reference symbols in different drawings indicates similar or identical items.

### DETAILED DESCRIPTION OF DRAWINGS

The following description in combination with the Figures is provided to assist in understanding the teachings disclosed herein. The following discussion will focus on specific implementations and embodiments of the teachings. This focus is provided to assist in describing the teachings, and should not be interpreted as a limitation on the scope or applicability of the teachings. However, other teachings can certainly be used in this application. The teachings can also be used in other applications, and with several different types of architectures, such as distributed computing architectures, client/server architectures, or middleware server architectures and associated resources.

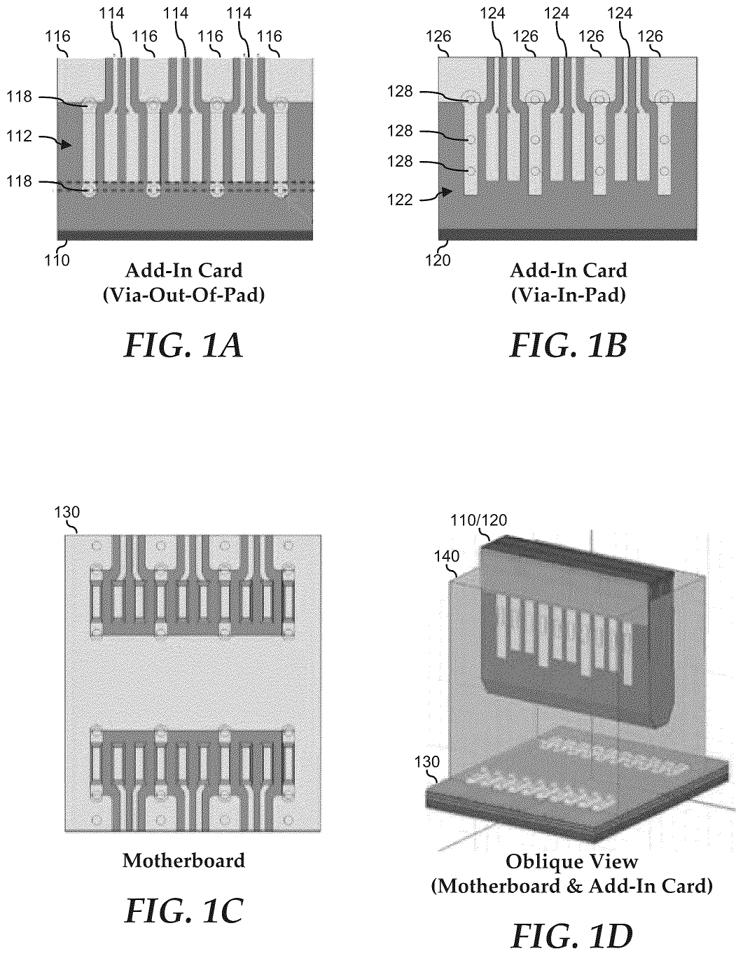

FIGS. 1A-1D illustrate various elements of an arrangement for connecting an add-in card to a mother board of an information handling system. Here, the add-in card will be understood to provide an additional function or feature to the operation of the information handling system, as needed or desired. In particular, FIGS. 1A and 1B illustrate portions of add-in cards 110 and 120, FIG. 1C illustrates a motherboard top-view of a motherboard 130 configured to connect to the add-in cards, and FIG. 1D illustrates an oblique-view of the arrangement of an add-in card connector 140 affixed to the motherboard, and including an installed add-in card. Add-in cards 110 and 120 are illustrated in top-view, with respective contact fingers 112 and 122 that interface with contacts in connector 130 to provide power connections, ground connections, and signal connections with motherboard 120. Contact fingers 112 and 122 are provided on the top and bottom surfaces of respective add-in cards 110 and 120. Contact fingers 110 and 120 each include respective signal contact fingers 114 and 124, and respective ground contact fingers 116 and 126.

Signal contact fingers 114 and 124 are configured to provide data signaling for various high-speed data communication interfaces, and may be configured as single-ended signaling where a single signal contact finger carries the desired signal, or as differential signaling where a differential pair of signal contact fingers carry the desired signal. In either case, it will be understood that ground contact fingers 116 and 126, in addition to providing a ground return for power to the add-in card, will also be provided to create a reference plane for respective signal contact fingers 114 and 124. In particular, ground contact fingers 116 and 126 operate as a ground plane against which single-ended signals are referenced, and as a shield layer between the signal contact fingers and any incident radiant energy, such as from crosstalk from adjacent signal contact fingers, or the like. In order to improve the effects of ground contact fingers 116 and 126, each of the ground contact fingers are connected to ground planes within the printed circuit boards (PCBs) of respective add-in cards 110 and 120 by associated ground vias 118 and 128. Not all of ground vias 118 and 128 are separately identified for simplicity of illustration.

In FIG. 1A, add-in card 110 represents a via-out-of-pad arrangement for ground vias 118. Signal contact fingers 114 are illustrated as having a characteristic length. This length is determined based upon the signal contacts and the depth of add-in card connector 140, and the length of signal contact fingers 114 may vary depending on the type of add-in card, the type of high-speed data communication interface, or other considerations, as needed or desired. In this configuration, a first of two (2) ground vias 118 is located at an end of ground contact finger 116 where the end of the ground contact finger is typically located at an edge of the PCB to form a card-edge connector. The other ground via is located inward from the edge of add-in card 110. It has been understood that extending the lengths of ground contact fingers 116 beyond the length of signal contact fingers 114, and locating the one (1) ground via 118 at the end of the ground contact finger, results in improved signal integrity of the signals carried by the signal contact fingers.

However as the signal speed of high-speed data communication interfaces has increased, the topology of ground contact fingers has had greater effects on the signal integrity of the signal contact fingers. Thus, in general, as signal speeds have increased, the ground contact fingers have gone from grounding on the surface layer only at slower speeds, to connecting to ground planes within the PCBs of the add-in cards, typically by a single ground via at the base of the ground contact finger at higher speeds, to connecting to the ground plane at both ends of the ground contact via (as illustrated herein, and as described as “via-out-of-pad” herein) at even higher speeds. As signal speeds have continued to increase, it has been discovered that the large voids between a ground contact finger, the ground vias at each end, and the underlying ground plane have, in effect, become resonate cavities that diminish the signal integrity of the associated signal contact fingers. However, the fabrication of the via-out-of-pad topology is easily within the capabilities of most PCB fabricators, and is thus a relatively cheap fabrication method.

In FIG. 1B, add-in card 120 represents a via-in-pad arrangement for ground vias 128. Again, signal contact fingers 124 are illustrated as having a characteristic length which may vary depending on the type of add-in card, the type of high-speed data communication interface, or other considerations, as needed or desired. And again, extending the lengths of ground contact fingers 126 beyond the length of signal contact fingers 124 results in improved signal integrity of the signals carried by the signal contact fingers. In this configuration, two (2) of three (3) ground vias 128 are located within the length of ground contact finger 126, and the third ground via is located inward from the edge of add-in card 120. However it has been discovered that by locating ground vias 118 within the limits of the length of signal contact fingers 114, the resulting cavities created by ground contact fingers 116, the ground vias, and the underlying ground plane are diminished, thereby reducing the adverse effects on the signal integrity of the signal contact fingers even further. However the fabrication of the via-in-pad topology is not within the capabilities of all PCB fabricators, and is thus a relatively expensive fabrication method. Thus the manufacturer of add-in cards is typically faced with a choice between providing cheaper add-in cards utilizing the via-out-of-pad topology, but with poorer signal performance, or providing more expensive add-in cards utilizing the via-in-pad topology, but with higher signal performance.

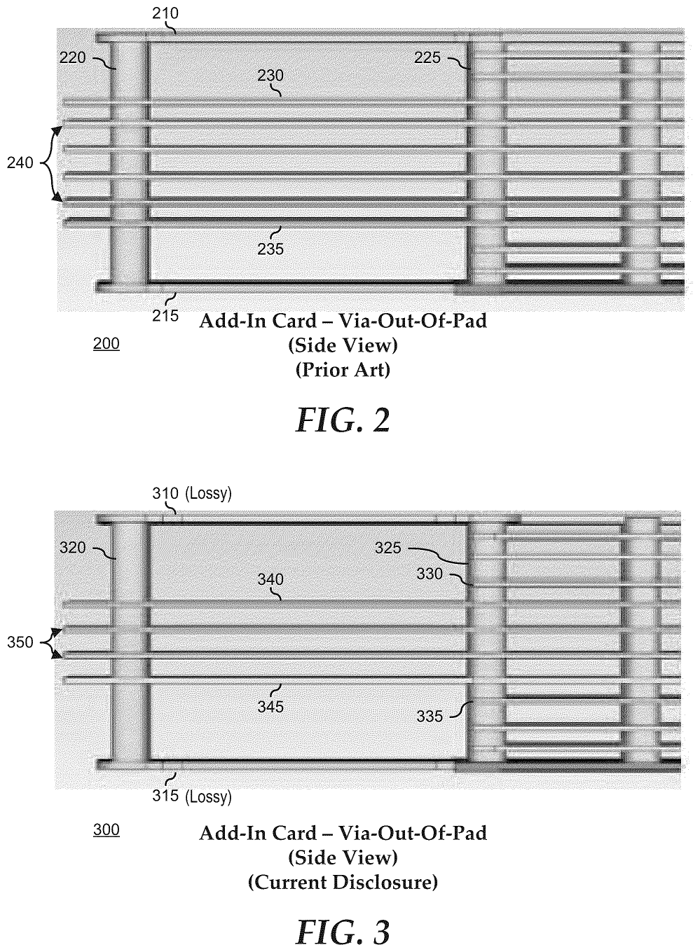

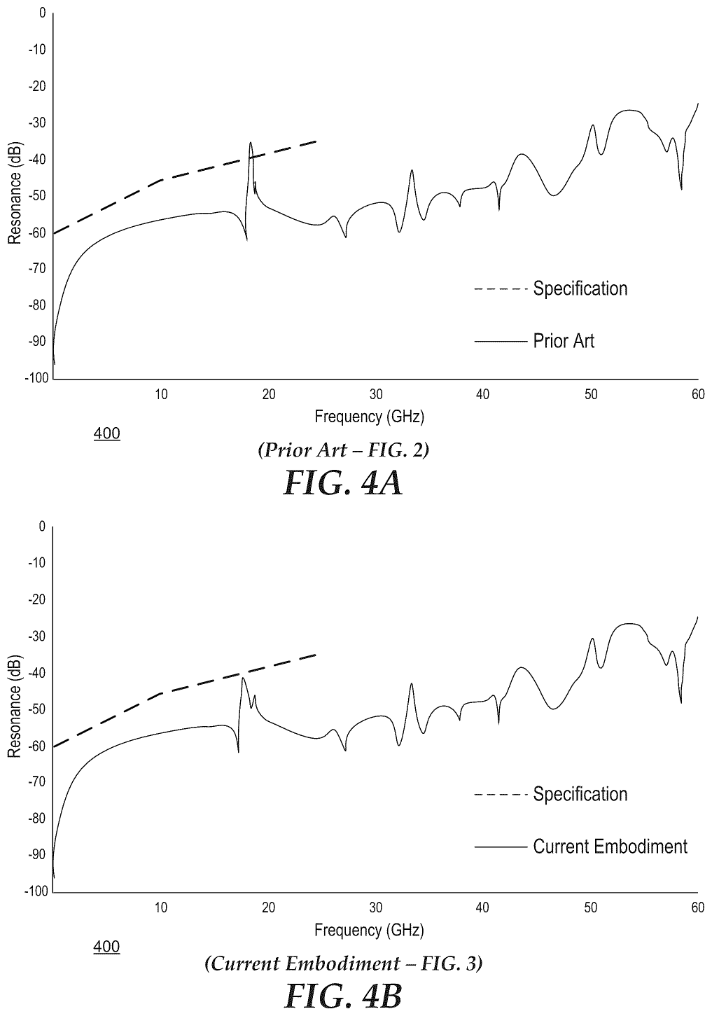

FIG. 2 illustrates a side-view of the ground layers of an add-in card 200 as may be known in the art. Add-in card 200 is fabricated utilizing a via-out-of-pad manufacturing method, and includes a top ground contact finger 210 and a bottom ground contact finger 215, similar to ground contact fingers 116 of FIG. 1A. Ground contact fingers 210 and 215 are connected together by a ground via 220 at a first end of the ground contact fingers, and by a ground via 225 at the other end of the ground contact fingers. Where the leftward side of add-in card 200 corresponds with an edge connector of the add-in card, then ground via 220 will be the “out-of-pad” via. Add-in card 200 is illustrated as having ten (10) internal metal layers and two (2) outer (that is, top and bottom) metal layers. Of the inner metal layers, there are a ground metal layer 230 nearest to top ground contact finger 210 and a ground metal layer 235 nearest to bottom ground contact finger 215. As illustrated herein ground metal layer 230 is on a fourth (L4) metal layer of add-in card 200, and ground metal layer 235 is on a ninth (L9) metal layer of the add-in card. Add-in card 200 includes four (4) additional inner ground metal layers 240. Metal layers 230, 235, and 240 are all connected to ground vias 220 and 225. As noted above, the voids that form resonate cavities that diminish the signal integrity of the associated signal contact fingers are here shown as the areas between ground contact finger 210, ground vias 220 and 225, and ground metal layer 230, and between ground contact finger 215, ground vias 220 and 225, and ground metal layer 235.

FIG. 3 illustrates a side-view of the ground layers of an add-in card 300 according to an embodiment of the current disclosure. Add-in card 300 is fabricated utilizing a via-out-of-pad manufacturing method, and includes a top ground contact finger 310 and a bottom ground contact finger 315, similar to ground contact fingers 116 of FIG. 1A. Ground contact fingers 310 and 315 are connected together by a ground via 320 at a first end of the ground contact fingers, and by a ground via 325 at the other end of the ground contact fingers. Where the leftward side of add-in card 300 corresponds with an edge connector of the add-in card, then ground via 320 will be the “out-of-pad” via. Add-in card 300 is illustrated as having ten (10) internal metal layers and two (2) outer (that is, top and bottom) metal layers. Of the inner metal layers, there are a ground metal layer 330 nearest to top ground contact finger 310 and a ground metal layer 335 nearest to bottom ground contact finger 315. As illustrated herein, ground metal layer 330 is on a fourth (L4) metal layer of add-in card 300, and ground metal layer 335 is on a ninth (L9) metal layer of the add-in card. However ground metal layers 330 and 335 are not fabricated to underlie respective top ground contact finger 310 and bottom ground contact finger 315, and neither of ground metal layers 330 and 335 are connected to ground via 320, but are terminated at ground via 325.

There is an additional ground metal layer 340 that is a next nearest ground meatal layer to top ground contact finger 310 and an additional ground metal layer 345 that is a next nearest metal layer to bottom ground contact finger 315. As illustrated herein, ground metal layer 340 is on a fifth (L5) metal layer of add-in card 300, and ground metal layer 345 is on an eighth (L8) metal layer of the add-in card. Add-in card 300 includes two (2) additional inner ground metal layers 250. Metal layers 240, 245, and 250 are all connected to ground vias 320 and 325. The voids that form resonate cavities that diminish the signal integrity of the associated signal contact fingers are shown as the areas between ground contact finger 310, ground vias 320 and 325, and ground metal layer 340, and between ground contact finger 315, ground vias 320 and 325, and ground metal layer 345.

In addition to moving the underlying ground metal layers in add-in card 300 from the closest ground metal layers, such as ground metal layers 230 and 235 as illustrated in FIG. 2, to the next closest ground metal layers 340 and 345, the add-in card utilizes ground contact fingers 310 and 315 that have deliberately been fabricated to be of a more lossy design than the typical metal as used in signal contact fingers of the add-in card. For example, ground metal layers 310 and 315 may be fabricated with a conductive material that is less conductive than the signal contact fingers and the metal layers of add-in card 300, may be fabricated of a common conductive material with the signal contact fingers and the metal layers, but with loss-inducing impurities add thereto, may be fabricated with a loss-inducing surface roughness as compared with the surfaced roughness of the signal contact fingers, or by other methods for inducing loss into the ground contact fingers. An example of a conductive material that is less conductive, assuming the base conductive material is copper, may include aluminum, zinc, nickel, or the like, and may include copper plated in an appropriate low-conductivity material. An example of a loss-inducing impurity may include lead, antimony, silver, nickel, phosphorus, or the like.

Loss-inducing surface roughness may be characterized by a profile roughness parameter, including an arithmetic average of absolute values parameter (Rₐ), a root mean square parameter (R_{q}), a skewness parameter (Rₛₖ), or another profile roughness parameter, as needed or desired. Copper coatings that are used to make signal and ground contact fingers may include commercially available copper coatings, such as rolled copper foils with an R_{q} surface roughness of around 0.4 micrometers (μm), electrodeposited copper foils with an R_{q} surface roughness of around 0.5 to 3.5 μm, and resistive copper foils with an R_{q} surface roughness of around 1.0 to 2.0 μm. For example ground contact fingers 310 and 315 may be manufactured using a rough copper coating such as an electrodeposited copper foil with an R_{q} surface roughness at the higher end of the available coatings, such as with an R_{q} of between 1.5 and 3.5 μm, or such as a resistive foil with a similar R_{q} value. Further, signal contact fingers can be manufactured using a smooth copper coating such as a rolled copper foil with an R_{q} surface roughness of around 0.4, or such as an electrodeposited copper foil with an R_{q} surface roughness at the lower end of the available coatings, such as with an R_{q} of between 0.5 and 1.5 μm.

FIGS. 4A and 4B are graphs illustrating the inventors' characterization of the resonance associated with a via-out-of-pad arrangement versus the frequency for the prior art configuration (FIG. 4A) and for the current embodiments (FIG. 4B). Note that utilizing the nearest ground metal layer for shielding ground contact fingers results in resonance that exceeds the specification for a particular high-speed data communication interface. On the other hand, utilizing the next nearest ground metal layer, in combination with increasing the loss of the ground contact finger results in a lower resonance that is within the specified limits.

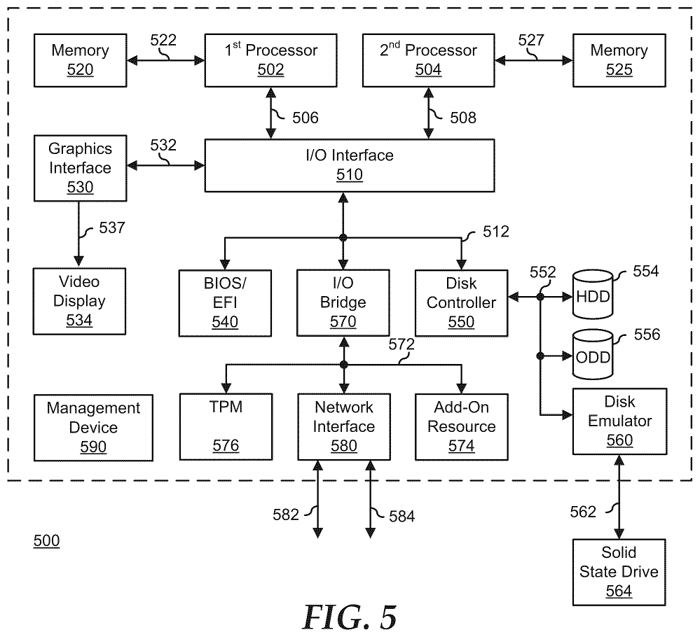

FIG. 5 illustrates a generalized embodiment of an information handling system 500. For purpose of this disclosure an information handling system can include any instrumentality or aggregate of instrumentalities operable to compute, classify, process, transmit, receive, retrieve, originate, switch, store, display, manifest, detect, record, reproduce, handle, or utilize any form of information, intelligence, or data for business, scientific, control, entertainment, or other purposes. For example, information handling system 500 can be a personal computer, a laptop computer, a smart phone, a tablet device or other consumer electronic device, a network server, a network storage device, a switch router or other network communication device, or any other suitable device and may vary in size, shape, performance, functionality, and price. Further, information handling system 500 can include processing resources for executing machine-executable code, such as a central processing unit (CPU), a programmable logic array (PLA), an embedded device such as a System-on-a-Chip (SoC), or other control logic hardware. Information handling system 500 can also include one or more computer-readable medium for storing machine-executable code, such as software or data. Additional components of information handling system 500 can include one or more storage devices that can store machine-executable code, one or more communications ports for communicating with external devices, and various input and output (I/O) devices, such as a keyboard, a mouse, and a video display. Information handling system 500 can also include one or more buses operable to transmit information between the various hardware components.

Information handling system 500 can include devices or modules that embody one or more of the devices or modules described below, and operates to perform one or more of the methods described below. Information handling system 500 includes a processors 502 and 504, an input/output (I/O) interface 510, memories 520 and 525, a graphics interface 530, a basic input and output system/universal extensible firmware interface (BIOS/UEFI) module 540, a disk controller 550, a hard disk drive (HDD) 554, an optical disk drive (ODD) 556, a disk emulator 560 connected to an external solid state drive (SSD) 562, an I/O bridge 570, one or more add-on resources 574, a trusted platform module (TPM) 576, a network interface 580, a management device 590, and a power supply 595. Processors 502 and 504, I/O interface 510, memory 520, graphics interface 530, BIOS/UEFI module 540, disk controller 550, HDD 554, ODD 556, disk emulator 560, SSD 562, I/O bridge 570, add-on resources 574, TPM 576, and network interface 580 operate together to provide a host environment of information handling system 500 that operates to provide the data processing functionality of the information handling system. The host environment operates to execute machine-executable code, including platform BIOS/UEFI code, device firmware, operating system code, applications, programs, and the like, to perform the data processing tasks associated with information handling system 500.

In the host environment, processor 502 is connected to I/O interface 510 via processor interface 506, and processor 504 is connected to the I/O interface via processor interface 508. Memory 520 is connected to processor 502 via a memory interface 522. Memory 525 is connected to processor 504 via a memory interface 527. Graphics interface 530 is connected to I/O interface 510 via a graphics interface 532, and provides a video display output 536 to a video display 534. In a particular embodiment, information handling system 500 includes separate memories that are dedicated to each of processors 502 and 504 via separate memory interfaces. An example of memories 520 and 530 include random access memory (RAM) such as static RAM (SRAM), dynamic RAM (DRAM), non-volatile RAM (NV-RAM), or the like, read only memory (ROM), another type of memory, or a combination thereof.

BIOS/UEFI module 540, disk controller 550, and I/O bridge 570 are connected to I/O interface 510 via an I/O channel 512. An example of I/O channel 512 includes a Peripheral Component Interconnect (PCI) interface, a PCI-Extended (PCI-X) interface, a high-speed PCI-Express (PCIe) interface, another industry standard or proprietary communication interface, or a combination thereof. I/O interface 510 can also include one or more other I/O interfaces, including an Industry Standard Architecture (ISA) interface, a Small Computer Serial Interface (SCSI) interface, an Inter-Integrated Circuit (I²C) interface, a System Packet Interface (SPI), a Universal Serial Bus (USB), another interface, or a combination thereof. BIOS/UEFI module 540 includes BIOS/UEFI code operable to detect resources within information handling system 500, to provide drivers for the resources, initialize the resources, and access the resources. BIOS/UEFI module 540 includes code that operates to detect resources within information handling system 500, to provide drivers for the resources, to initialize the resources, and to access the resources.

Disk controller 550 includes a disk interface 552 that connects the disk controller to HDD 554, to ODD 556, and to disk emulator 560. An example of disk interface 552 includes an Integrated Drive Electronics (IDE) interface, an Advanced Technology Attachment (ATA) such as a parallel ATA (PATA) interface or a serial ATA (SATA) interface, a SCSI interface, a USB interface, a proprietary interface, or a combination thereof. Disk emulator 560 permits SSD 564 to be connected to information handling system 500 via an external interface 562. An example of external interface 562 includes a USB interface, an IEEE 5394 (Firewire) interface, a proprietary interface, or a combination thereof. Alternatively, solid-state drive 564 can be disposed within information handling system 500.

I/O bridge 570 includes a peripheral interface 572 that connects the I/O bridge to add-on resource 574, to TPM 576, and to network interface 580. Peripheral interface 572 can be the same type of interface as I/O channel 512, or can be a different type of interface. As such, I/O bridge 570 extends the capacity of I/O channel 512 when peripheral interface 572 and the I/O channel are of the same type, and the I/O bridge translates information from a format suitable to the I/O channel to a format suitable to the peripheral channel 572 when they are of a different type. Add-on resource 574 can include a data storage system, an additional graphics interface, a network interface card (NIC), a sound/video processing card, another add-on resource, or a combination thereof. Add-on resource 574 can be on a main circuit board, on separate circuit board or add-in card disposed within information handling system 500, a device that is external to the information handling system, or a combination thereof.

Network interface 580 represents a NIC disposed within information handling system 500, on a main circuit board of the information handling system, integrated onto another component such as I/O interface 510, in another suitable location, or a combination thereof. Network interface device 580 includes network channels 582 and 584 that provide interfaces to devices that are external to information handling system 500. In a particular embodiment, network channels 582 and 584 are of a different type than peripheral channel 572 and network interface 580 translates information from a format suitable to the peripheral channel to a format suitable to external devices. An example of network channels 582 and 584 includes InfiniBand channels, Fibre Channel channels, Gigabit Ethernet channels, proprietary channel architectures, or a combination thereof. Network channels 582 and 584 can be connected to external network resources (not illustrated). The network resource can include another information handling system, a data storage system, another network, a grid management system, another suitable resource, or a combination thereof.

Management device 590 represents one or more processing devices, such as a dedicated baseboard management controller (BMC) System-on-a-Chip (SoC) device, one or more associated memory devices, one or more network interface devices, a complex programmable logic device (CPLD), and the like, that operate together to provide the management environment for information handling system 500. In particular, management device 590 is connected to various components of the host environment via various internal communication interfaces, such as a Low Pin Count (LPC) interface, an Inter-Integrated-Circuit (I2C) interface, a PCIe interface, or the like, to provide an out-of-band (OOB) mechanism to retrieve information related to the operation of the host environment, to provide BIOS/UEFI or system firmware updates, to manage non-processing components of information handling system 500, such as system cooling fans and power supplies. Management device 590 can include a network connection to an external management system, and the management device can communicate with the management system to report status information for information handling system 500, to receive BIOS/UEFI or system firmware updates, or to perform other task for managing and controlling the operation of information handling system 500. Management device 590 can operate off of a separate power plane from the components of the host environment so that the management device receives power to manage information handling system 500 when the information handling system is otherwise shut down. An example of management device 590 include a commercially available BMC product or other device that operates in accordance with an Intelligent Platform Management Initiative (IPMI) specification, a Web Services Management (WSMan) interface, a Redfish Application Programming Interface (API), another Distributed Management Task Force (DMTF), or other management standard, and can include an Integrated Dell Remote Access Controller (iDRAC), an Embedded Controller (EC), or the like. Management device 590 may further include associated memory devices, logic devices, security devices, or the like, as needed or desired.

Although only a few exemplary embodiments have been described in detail herein, those skilled in the art will readily appreciate that many modifications are possible in the exemplary embodiments without materially departing from the novel teachings and advantages of the embodiments of the present disclosure. Accordingly, all such modifications are intended to be included within the scope of the embodiments of the present disclosure as defined in the following claims. In the claims, means-plus-function clauses are intended to cover the structures described herein as performing the recited function and not only structural equivalents, but also equivalent structures.

The above-disclosed subject matter is to be considered illustrative, and not restrictive, and the appended claims are intended to cover any and all such modifications, enhancements, and other embodiments that fall within the scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. An add-in card configured to be installed into an information handling system, the add-in card comprising:
a first card-edge connector disposed on a first surface of the add-in card, the first card-edge connector including a first signal contact finger to carry a first signal of the add-in card, and a first ground contact finger coupled to a ground plane of the add-in card;
a plurality of metal layers in a printed circuit board of the add-in card, the metal layers including a first surface metal layer on the first surface of the printed circuit board, a first ground metal layer, and a second ground metal layer, wherein the first surface metal layer includes the first signal contact finger and the first ground contact finger, wherein the first ground metal layer is a closest metal layer to the first surface metal layer, and wherein the second ground metal layer is farther from the first surface metal layer than the first ground metal layer;
a first ground via coupled to a first end of the first ground contact finger, the first ground metal layer, and the second ground metal layer; and
a second ground via coupled to a second end of the first ground contact finger and the second ground metal layer, but is not coupled to the first ground metal layer.

2. The add-in card of claim 1, wherein a portion of the second ground metal layer between the first ground via and the second ground via is disposed under the ground contact finger.

3. The add-in card of claim 2, wherein the first signal contact finger has a first length, and the first ground contact finger has a second length greater than the first length, wherein the first ground contact finger extends beyond the first signal contact finger at the second end of the first ground contact finger.

4. The add-in card of claim 3, wherein the second ground via is coupled to the first ground contact finger in a via-out-of-pad configuration.

5. The add-in card of claim 1, further comprising:
a second card-edge connector disposed on a second surface of the add-in card, the second card-edge connector including a second signal contact finger to carry a second signal of the add-in card, and a second ground contact finger coupled to the ground plane;
wherein the metal layers further include a second surface metal layer on the second surface of the printed circuit board, a third ground metal layer, and a fourth ground metal layer, wherein the second surface metal layer includes the second signal contact finger and the second ground contact finger, wherein the third ground metal layer is a closest metal layer to the second surface metal layer, and wherein the fourth ground metal layer is farther from the second surface metal layer than the third ground metal layer;
wherein the first ground via is further coupled to a first end of the second ground contact finger, the first ground metal layer, and the second ground metal layer; and
wherein the second ground via is further coupled to a second end of the second ground contact finger and the second ground metal layer.

6. The add-in card of claim 1, wherein the first ground contact finger is configured to be more electrically lossy than the first signal contact finger.

7. The add-in card of claim 6, wherein, in configuring the first ground contact finger to be more electrically lossy than the first signal contact finger, the first ground contact finger is formed of a first material and the first signal contact finger is formed of a second material different from the first material.

8. The add-in card of claim 7, wherein a conductivity of the first material is lower than a conductivity of the second material.

9. The add-in card of claim 6, wherein, in configuring the first ground contact finger to be more electrically lossy than the first signal contact finger, the first ground contact finger is formed with an impurity that decreases the conductivity of the first ground contact finger.

10. The add-in card of claim 6, wherein, in configuring the first ground contact finger to be more electrically lossy than the first signal contact finger, the first ground contact finger is formed with a surface roughness that is greater than a surface roughness of the first signal finger.

11. A method for forming an add-in card configured to be installed into an information handling system, the method comprising:
providing, on a first surface of the add-in card, a first card-edge connector, the first card-edge connector including a first signal contact finger to carry a first signal of the add-in card, and a first ground contact finger coupled to a ground plane of the add-in card;
providing a plurality of metal layers in the add-in card, the metal layers including a first surface metal layer on the first surface of the printed circuit board, a first ground metal layer, and a second ground metal layer, wherein the first surface metal layer includes the first signal contact finger and the first ground contact finger, wherein the first ground metal layer is a closest metal layer to the first surface metal layer, and wherein the second ground metal layer is farther from the first surface metal layer than the first ground metal layer;
coupling a first ground via of the add-in card to a first end of the first ground contact finger, the first ground metal layer, and the second ground metal layer; and
coupling a second ground via coupled to a second end of the first ground contact finger and the second ground metal layer, but is not coupled to the first ground metal layer.

12. The method of claim 11, wherein a portion of the second ground metal layer between the first ground via and the second ground via is disposed under the ground contact finger.

13. The method of claim 12, wherein the first signal contact finger has a first length, and the first ground contact finger has a second length greater than the first length, wherein the first ground contact finger extends beyond the first signal contact finger at the second end of the first ground contact finger.

14. The method of claim 3, wherein the second ground via is coupled to the first ground contact finger in a via-out-of-pad configuration.

15. The method of claim 11, further comprising:
providing, on a second surface of the add-in card, a second card-edge connector, the second card-edge connector including a second signal contact finger to carry a second signal of the add-in card, and a second ground contact finger coupled to the ground plane;
wherein the metal layers further include a second surface metal layer on the second surface of the printed circuit board, a third ground metal layer, and a fourth ground metal layer, wherein the second surface metal layer includes the second signal contact finger and the second ground contact finger, wherein the third ground metal layer is a closest metal layer to the second surface metal layer, and wherein the fourth ground metal layer is farther from the second surface metal layer than the third ground metal layer;
wherein the first ground via is further coupled to a first end of the second ground contact finger, the first ground metal layer, and the second ground metal layer; and
wherein the second ground via is further coupled to a second end of the second ground contact finger and the second ground metal layer.

16. The method of claim 11, wherein the first ground contact finger is configured to be more electrically lossy than the first signal contact finger.

17. The method of claim 16, wherein, in configuring the first ground contact finger to be more electrically lossy than the first signal contact finger, the first ground contact finger is formed of a first material and the first signal contact finger is formed of a second material different from the first material, wherein a conductivity of the first material is lower than a conductivity of the second material.

18. The method of claim 16, wherein, in configuring the first ground contact finger to be more electrically lossy than the first signal contact finger, the first ground contact finger is formed with an impurity that decreases the conductivity of the first ground contact finger.

19. The method of claim 16, wherein, in configuring the first ground contact finger to be more electrically lossy than the first signal contact finger, the first ground contact finger is formed with a surface roughness that is greater than a surface roughness of the first signal finger.

20. An add-in card configured to be installed into an information handling system, the add-in card comprising:
a first card-edge connector disposed on a first surface of the add-in card, the first card-edge connector including a first signal contact finger to carry a first signal of the add-in card, and a first ground contact finger coupled to a ground plane of the add-in card;
a second card-edge connector disposed on a second surface of the add-in card, the second card-edge connector including a second signal contact finger to carry a second signal of the add-in card, and a second ground contact finger coupled to the ground plane;
a plurality of metal layers in a printed circuit board of the add-in card, the metal layers including a first surface metal layer on the first surface of the printed circuit board, a second surface metal layer on the second surface of the printed circuit board, a first ground metal layer, a second ground metal layer, a third ground metal layer, and a fourth ground metal layer, wherein the first surface metal layer includes the first signal contact finger and the first ground contact finger, wherein the second surface metal layer includes the second signal contact finger and the second ground contact finger, wherein the first ground metal layer is a closest metal layer to the first surface metal layer, the second ground metal layer is farther from the first surface metal layer than the first ground metal layer, the third ground metal layer is a closest metal layer to the second surface metal layer, and the fourth ground metal layer is farther from the second surface metal layer than the third ground metal layer;
a first ground via coupled to a first end of the first ground contact finger, a first end of the second ground contact finger, the first ground metal layer, the second ground metal layer, the third ground metal layer, and the fourth ground metal layer; and
a second ground via coupled to a second end of the first ground contact finger, a second end of the second ground contact finger, the second ground metal layer and the fourth ground metal layer, but is not coupled to the first ground metal layer or the third ground metal layer;
wherein the first ground contact finger is configured to be more electrically lossy than the first signal contact finger, and the second ground contact finger is configured to be more electrically lossy than the second signal contact finger.
